(19) United States
(12) Patent Application Publication
(10) Pub. No.: US 2008/0297224 A1
(43) Pub. Date: Dec. 4, 2008

(54) Minimizing Static Current Consumption While Providing Higher-Swing Output Signals when Components of an Integrated Circuit are Fabricated using a Lower-Voltage Process

(75) Inventor: Karthik Rajagopal, Bangalore (IN)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/120,660

(22) Filed: May 15, 2008

Related U.S. Application Data
(60) Provisional application No. 60/941,366, filed on Jun. 1, 2007.

(51) Int. Cl. H03L 5/00

(52) U.S. Cl. 327/333

(57) ABSTRACT

An aspect of the present invention minimizes static current consumption in an output block which receives a lower strength input signal and drives a corresponding output signal with a higher strength. Such a feature may be obtained while ensuring that no closed path exists between a first and second reference potentials (having voltage levels equaling upper and lower limits of the swing of the output signal) used by a circuit portion driving a pair of transistors operating as an inverter in the output block. In one embodiment, such a closed path is avoided during the steady state of the output signal, while in an alternative embodiment, the closed path is avoided during the transitions as well.

### RELATED APPLICATION(S)

The present application is related to co-pending non-provisional U.S. application Ser. No. 11/959,496, entitled “Providing Higher-Swing Output Signals When Components Of An Integrated Circuit Are Fabricated Using A Lower-Voltage Process”; (hereafter RELATED APPLICATION).

The present application claims priority from co-pending U.S. provisional application Ser. No. 60/941,366, entitled: “Zero Static Current 3.3V/1.8V Driver in 1.8V Process”, filed on: Jun. 1, 2007 and the same inventor (Karthik Rajagopal) as in the subject application as inventor, attorney docket number: TI-64829PS, and is incorporated in its entirety herewith.

### BACKGROUND

1. Field of the Technical Disclosure

The present disclosure relates generally to integrated circuit (IC) design, and more specifically to techniques for minimizing static current consumption providing output signals with higher signal swing strengths using integrated circuit (IC) components fabricated using lower-voltage processes.

2. Related Art

An integrated circuit (IC) generally contains various types of components such as transistors, resistors, capacitors, etc, which are interconnected according to desired design specification. ICs are generally formed by fabrication, which generally entails depositing various semi-conductor material and interconnecting paths to form the desired components, as is well known in the relevant arts.

Various characteristics of the material thus formed (constituting an IC) define a fabrication process. Such characteristics generally include the material used, the sequence in which the material is deposited, thickness, width, length of the various layers/material, as is well known in the relevant arts.

Such fabrication processes are often tailored for operation of the IC at different power supplies. For example, to operate with a higher voltage power supply, it may be generally required to have material of more thickness, which would enable the components to withstand higher voltages. A fabrication process tailored for a voltage of a specific magnitude is termed as a process of a corresponding voltage. Examples of such different processes include 3.3 V CMOS process, 1.8 V CMOS process, etc.

There are often scenarios when an IC is required to provide higher-swing output signals when components of an integrated circuit are fabricated using a lower-voltage process. For example, it may be desirable to implement at least some portions (e.g., a core portion containing the main functional part of the IC or an output block) using a lower voltage process (for advantages such as lower power consumption, reduced area requirements, etc.), while the output signals may need to be provided at a higher voltage level as well (for reasons such as legacy compatibility, to provide stronger signals, etc.).

As is well appreciated, it is generally desirable to fabricate the entire circuit (of an IC) using the same fabrication process (of lower voltage). Such fabrication may need to be performed to meet various requirements of integrated circuits potentially specific to the environment in which they are deployed, including minimizing static current consumption.

Static current generally refers to current consumed by a circuit or an IC to bias (provide voltages, currents) various components/nodes in the IC at desired operating points, as against current consumed in representing signals. For example, assuming a voltage V volts is desired at a node, such voltage may be obtained by using a potential divider using resistors or other components. In the example noted above, the potential divider may consume a static current in providing the desired voltage V. As another example, components such as transistors are often biased at desired operating points. Such biasing may also cause static currents to flow in an IC.

Several aspects of the present invention enable minimizing static current consumption while providing higher-swing output signals when components of an integrated circuit are fabricated using a lower-voltage process.

### BRIEF DESCRIPTION OF THE DRAWINGS

The present invention will be described with reference to the following accompanying drawings, which are described briefly below.

FIG. 1A is a block diagram of an example environment in which several aspects of the present invention can be implemented.

FIG. 1B is a waveform of the output of an output block used to illustrate portions corresponding to which static current consumption is reduced.

FIG. 2 is a block diagram of an output block consuming reduced static current in an embodiment of the present invention.

FIG. 3 is a circuit diagram illustrating the internal details of a driver block controlling an output transistor in an output block in an embodiment of the present invention.

FIG. 4 is a circuit diagram illustrating the internal details of another driver block controlling another output transistor in an output block in an embodiment of the present invention.

FIG. 5 is a block diagram of an output block in another embodiment of the present invention.

FIG. 6 is a block diagram of an improved driver block in an embodiment of the present invention.

FIG. 7 is a circuit diagram illustrating the internal details of a differential amplifier used in a driver block in an embodiment of the present invention.

FIG. 8 is a circuit diagram illustrating the internal details of a hold-and-turn-off circuit in an embodiment of the present invention.

FIG. 9 is a circuit diagram illustrating the internal details of a level shifter of a driver block in an embodiment of the present invention.

FIG. 10 is a circuit diagram illustrating the internal details of another differential amplifier used in another driver block in an embodiment of the present invention.

FIG. 11 is a circuit diagram illustrating the internal details of another hold-and-turn-off circuit in an embodiment of the present invention.

FIG. 12 is a circuit diagram illustrating a portion of pad detector circuit in an embodiment of the present invention.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

An aspect of the present invention minimizes static current consumption in an output block which receives a lower strength (e.g., lower voltage) input signal and drives a corresponding output signal with a higher strength (e.g., higher voltage). Such a feature may be obtained while ensuring that no closed path exists between a first and second reference potentials (having voltage levels equaling upper and lower limits of the swing of the output signal) used by a circuit portion driving a pair of transistors operating as an inverter in the output block. Such a closed path is avoided during the steady state of the output signal.

The output block may also contain a third reference potential (e.g., another power supply terminal) which enables the output block to optionally provide an output signal with a corresponding (different) voltage swing, with no closed path existing between any of the first reference potential, the second reference potential and the third reference potential when the output signal is in a steady state.

According to an aspect of the present invention, such features are provided when providing higher swing output signals when the components of an integrated circuit are fabricated using a lower voltage process.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. Example Environment

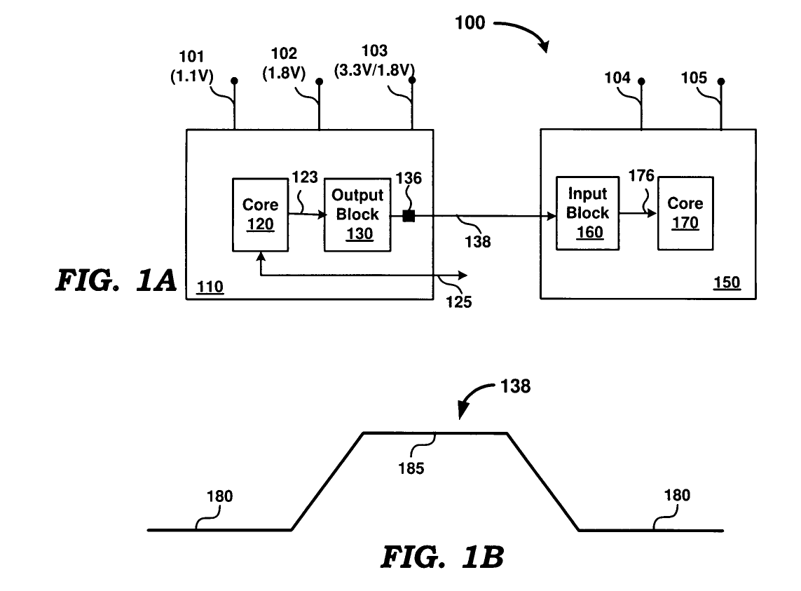

FIG. 1A is a block diagram of an example environment in which several aspects of the present invention can be implemented. System 100 is shown containing IC 110 and IC 150. For illustration, it is assumed that output block 130 of IC 110 is fabricated according to a 1.8V process (lower voltage process), while output signal 138 is to be provided at a 3.3 V level (higher voltage) and thus required to support higher voltage swing (0 to 3.3 V). In addition, at least optionally, output signal 138 may also be provided at a 1.8V level (0 to 1.8V swing). Core 120 may be fabricated using a 1.1V or 1.8V process. IC 150 may be fabricated using corresponding processes.

It should be appreciated that 1.8V and 3.3V are merely examples of lower and higher voltages. However, several features of the present invention may be implemented with other combinations (possibly with more levels being used within the same integrated circuit) of voltage levels and processes, as will be apparent to one skilled in the relevant arts by reading the disclosure provided herein. The details of each IC are described below in further detail.

IC 110 is shown containing core 120 and output block 130. IC 150 is shown containing core 170 and input block 160.

IC 110 receives a 1.1V power supply via path 101, a 1.8V supply via path 102, and either a 3.3V or 1.8V power supply via path 103. The 1.1V power supply may be provided for the operation of core 120. Core 120 generates signals with a swing of 0-1.1V, and provides the signals to output block 130. Core 120 may correspond to a central processing unit (CPU), and may also provide/receive 0-1.1V signals on path 125 to/from other circuits, not shown.

In an embodiment, the signal on each of the paths 123 and 138 represents a digital signal, with a voltage level of 0V representing one binary value and 1.1V representing the other binary value on path 123, and a voltage level of 0V representing one binary value and 3.3V representing the other binary value on path 138. Optionally, the digital signal on path 138 may be provided at a voltage level of 0V to represent one binary value and 1.8V to represent the other binary value. Thus, the voltage on path 123 swings between 0V and 1.1V, while the voltage on path 138 swings between 0V and 3.3V.

Output block 130 receives 0-1.1V swing signals from core 120 via path 123, and forwards the received signals on path 138 (via IC pad 136) with a higher swing of 0-3.3V (or with a swing of 0-1.8V). Output block 130 contains components fabricated according to a lower-voltage process (1.8V process in this example), but designed to provide a higher output signal swing 0V-3.3V.

IC 150 receives a 1.1V power supply via path 105, and a 3.3V (or 1.8V) power supply via path 104. The 1.1 V power supply supplies power to core 170, as well as portions of input blocks 160. Input block 160 receives the higher swing 0-3.3V (or 0- 1.8V) signals and forwards the signals as 0-1.1V on path 176 to core 170.

Several aspects of the present invention enable output block 130 to be implemented with several advantages, including reduced (minimal or zero) static current consumption, as described next with respect to examples. Reduced (minimal or zero) static current is drawn (between any of multiple reference potentials such as power, ground etc., connected to output block 130) when output signal 138 is in a steady state (corresponding to the steady voltages of any one of the two logic levels of signal 138, marked as non-transitioning portions 180 and 185 in FIG. 1B). Several embodiments of output block 130 are described next.

### 3. Output Block With Reduced Static Current Consumption in an Embodiment

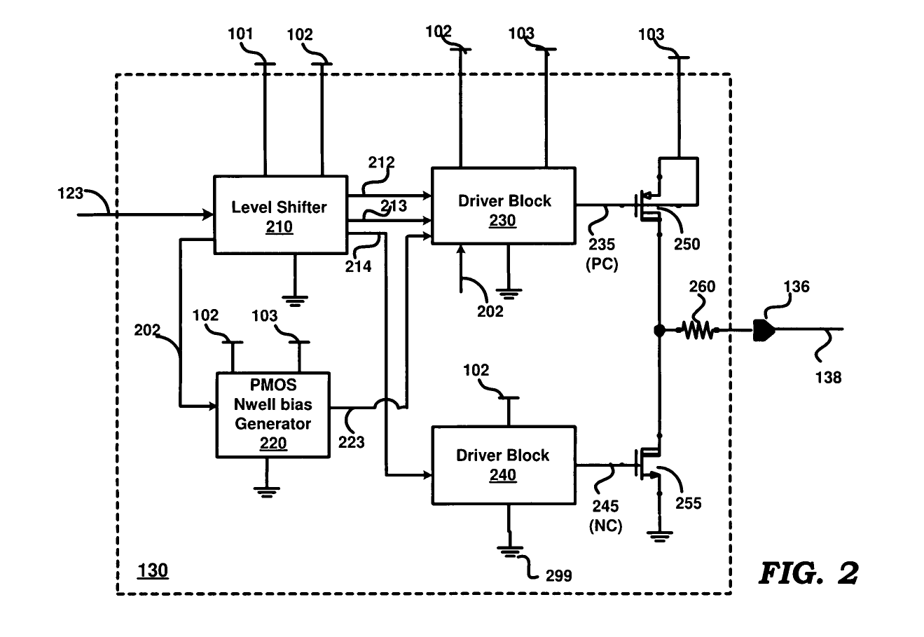

FIG. 2 is a block diagram of an output block consuming reduced static current in an embodiment of the present invention. Output block 130 is shown containing level shifter 210, PMOS nwell bias generator 220, driver blocks 230 and 240, drain extended P-type metal oxide semiconductor transistor (DEPMOS) 250, drain extended N-type metal oxide semiconductor transistor (DENMOS) 255, and resistor 260. Each component/block of FIG. 2 is described below.

Level shifter 210 receives digital signals with a lower voltage swing (0-1.1V in the example) via path 123, and in response provides complementary level-shifted signals with voltage swing 0-1.8V on paths 212 and 213 to driver block 230, and path 214 to driver block 240. As described below, the level-shifted signals on paths 212 and 213 are complementary to each other (complementary logic levels). For ease of reference, signals 212 and 213 are also referred to below as PC18 and PCZ18, while signal 214 is referred to as NC18.

Level shifter 210 generates a signal MODE18 on path 202 specifying mode of operation of output block 130 (mode specifying whether output on path 138 is desired at 1.8V (1.8V mode) or 3.3V (3.3V mode) levels). MODE18 is a 1.8V level signal and is provided to PMOS nwell bias generator 220 and driver block 230. Path 103 receives a 3.3V power supply when the 3.3V mode of operation is desired, but receives a 1.8V power supply when the 1.8V mode of operation is desired.

Merely to simplify the description below, it is assumed that level-shifter 210 generates signals PC18, PCZ18 and NC18 having the following relationship to input data 123:

When input 123 is at logic 1, PC18 is at logic 0, PCZ18 is at logic 1 (complement of PC18), and NC18 is at logic 0.

When input 123 is at logic 0, PC18 is at logic 1, PCZ18 is at logic 0, and NC18 is at logic 1.

PMOS nwell bias generator 220 generates a signal (PMOS NWELL BIAS) on path 223 to bias NWELLs of the corresponding transistors in driver block 230 to a potential that is higher of the two voltages 1.8V (on path 102) and 3.3V (on path 103). The generation of the PMOS NWELL BIAS signal enables minimization of latch-up issues during event of power-up of the circuit contained in output block 130. During normal operating conditions the voltage on signal PMOS NWELL BIAS equals voltage 103, irrespective of whether output on path 138 is desired at 1.8V or 3.3V levels. Level shifter 210 and PMOS nwell bias generator 220 may be implemented in a known way. Resistor 260 is provided for impedance matching purposes.

Driver block 230 receives level shifted signals 212 and 213 (and additionally other signals as described below), and correspondingly generates a signal (PC) on path 235 to switch on or off DEPMOS 250. Signal PC has a swing of 1.8V to 3.3V in the 3.3V mode of operation, while having a swing of 0V to 1.8V in the 1.8V mode of operation. Similarly, driver block 240 receives level shifted signal 214 (NC18), and correspondingly generates a signal (NC) on path 245 to switch on or off DENMOS 255. Signal NC has a swing of 0V to 1.8V in the both the 3.3V as well as 1.8V mode of operation.

Thus, DEPMOS 250 and DENMOS 255 may be viewed as a pair of “output transistors” operated to provide the output signal 138, and driver blocks 230 and 240 may be viewed as generating control signals to control the (on/off) operation of the “output” transistors. It is noted that DEPMOS 250 and DENMOS 255 are fabricated using a 1.8V process, but can reliably withstand voltages of greater than 1.8V (e.g., 3.3V) across their respective gate-to-drain and drain-to-source terminals due to the drain extended construction. However, it should be appreciated that any alternative techniques/technologies which can withstand such higher voltage swings can also be employed, without departing from the scope and spirit of various aspects the present invention, as will be apparent to one skilled in the relevant arts.

In an embodiment, when input signal 123 is a logic low (0V), signal PC is at a logic high (3.3V or 1.8V, depending on signal MODE18), and signal NC is also at a logic high (1.8V). As a result, output 138 is at logic low (0V).

On the other hand, when input signal 123 is a logic high (1.1V), signal PC is at a logic low (1.8V or 0V, depending on signal MODE18), and signal NC is also at a logic low (0V). As a result, output 138 is at logic high (3.3V or 1.8V, depending on signal MODE18).

The internal circuit details as well as operation of driver blocks 230 and 240 are described next.

### 4. Driver Blocks

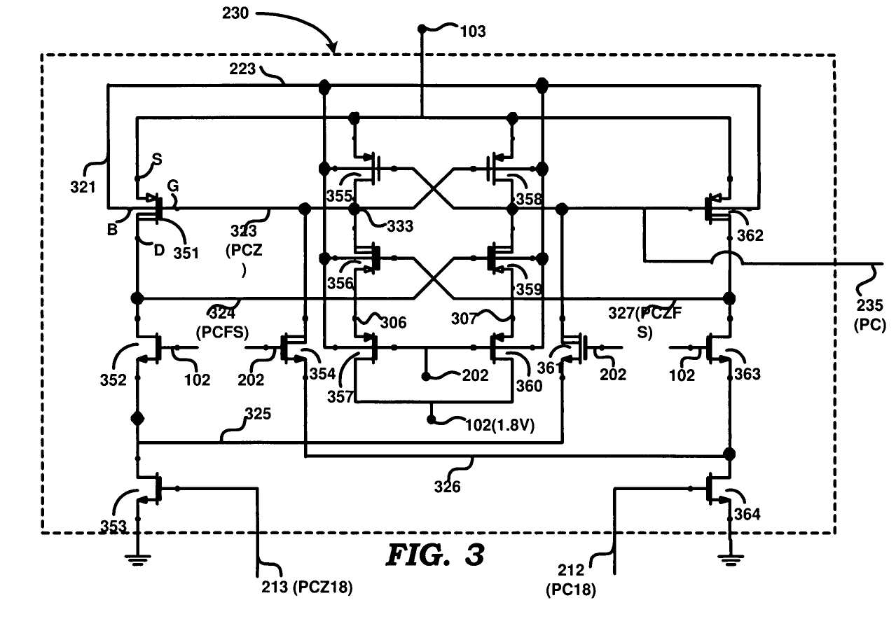

FIG. 3 is a circuit diagram illustrating the internal details of a driver block controlling a DEPMOS output transistor in an output block in an embodiment of the present invention. It is assumed in the following description that driver block 230 of FIG. 3 generates control signal (PC) to control the operation of DEPMOS 250 of FIG. 2. For convenience, and at least to distinguish from other transistors in the circuit, DEPMOS 250 is also referred to below as P-output transistor. Similarly, DENMOS 255 (FIG. 2) is also referred to below as N-output transistor. Driver block 230 of FIG. 3 is shown containing DEPMOS 351, 356,359 and 362, DENMOS 354 and 361, P-type MOS transistors (PMOS) 355, 357, 358 and 360, N-type MOS transistors (NMOS) 352, 353, 363 and 364.

It is noted that DEPMOS and DENMOS transistors of FIG. 3 are fabricated using a 1.8V process, but having a drain-extended construction can reliably withstand voltages of greater than 1.8V (e.g., 3.3V) across their respective gate-to-drain and drain-to-source terminals. Gate, source, bulk and drain terminals of DEPMOS 351 are marked in FIG. 3 as G, S, B and D respectively. Corresponding terminals (where shown) of other transistors have similar meanings. Signal PMOS NWELL BIAS (223) generated by PMOS nwell bias generator 220 (FIG. 2) is provided to the bulk terminals of transistors 351, 355, 356, 357, 358, 359, 360 and 362.

It should be appreciated that the specific type of transistors (PMOS, NMOS, etc.) are chosen here merely for illustration. However, alternative embodiments using different configurations and transistors will be apparent to one skilled in the relevant arts by reading the disclosure provided herein. For example, the PMOS and NMOS transistors may be interchanged, while also interchanging the connections to power and ground terminals.

Accordingly, in the present application, the power and ground terminals are also referred to as reference potentials, the source and drain terminals (though which a current path is provided when turned on and an open path is provided when turned off) are termed as current terminals, and the gate terminal is termed as a control terminal.

Furthermore, though the terminals are shown with direct connections to various other terminals, it should be appreciated that additional components (as suited for the specific environment) may also be present in the path, and accordingly the connections may be viewed as being electrically coupled to the same connected terminals.

Also, while logic levels of the various signals are noted as corresponding to specific voltages (e.g., 0V, 1.8V, 3.3V etc), it must be understood that such voltages may be allowed to vary within appropriate ranges while still ensuring the corresponding logic levels, as is well known in he relevant arts. The operation of driver block 230 is described next, assuming 3.3V mode of operation.

In the 3.3V mode of operation, MODE18 signal (202) is at logic low (at or near 0V). As a result PMOS 357 and 360 are on, and nodes 306 and 307 have a voltage of 1.8V (from power supply 102). Assuming data 123 provided to level-shifter 210 (FIG. 2) is at a logic level (logic high in the example embodiment) such that nodes PC18 is at logic low (0V) and PCZ18 is at logic high (1.8V), NMOS 353 is on, while NMOS 364 is off. Since DENMOS 361 is also off (due to signal 202 being 0V), and thus the combination of NMOS 353 and DENMOS 361 do not affect node PC (235).

NMOS 352 is on since the gate terminal is connected to 1.8V (102). (It is noted here that NMOS 363 is also on since its gate terminal is connected to 1.8V (102)). Assuming the previous state of the circuit of FIG. 3 was such that node PCFS (324) is presently at 0V, DEPMOS 359 will be turned on since its source to gate voltage is 1.8V. Since DEPMOS 359 is on, its drain terminal is at 1.8V, i.e., node PC is at 1.8V. Referring to FIG. 2, a 1.8V at node PC turns on DEPMOS 250. It is noted below that DENMOS 255 (of FIG. 2) will be off under the present scenario. As a result, output node 138 is at a logic high of 3.3V (provided by power supply 103).

Continuing with the description of FIG. 3, since node PC is at 1.8V, PMOS 355 is on, and a voltage of 3.3V is produced at node PCZ (323). As a result, PMOS 358 and DEPMOS 351 are switched off. Also, since node PC is at 1.8V, DEPMOS 362 is switched on, and 3.3V is provided at node PCZFS (327), thereby switching off DEPMOS 356.

To summarize, for the condition (PC18=0V and PCZ18=1.8V, corresponding to one logic level of input 123), node PC is at 1.8V. Although not described in detail, it may be verified (for example, from the symmetry of the circuit structure of FIG. 3) that a complementary condition of node PC driven to 3.3V (with node PCZ driven to 1.8V) is achieved for the condition (PC18=1.8V and PCZ18=0V, corresponding to the other logic level of input 123). Node PC thus swings between 1.8V (switching on DEPMOS 250) and 3.3V (switching off DEPMOS 250).

The gate terminals of transistors 357 and 360 gates are at 0V during 3.3V mode of operation, and their bulk terminals are at 3.3V. However, gate oxides of transistors 357 and 360 are subjected to a voltage difference of 1.8V only, since these transistors are on and their channels are at 1.8V. Transistors 357, 360, 356 and 351 are protected from gate-oxide damage by channel shielding effect.

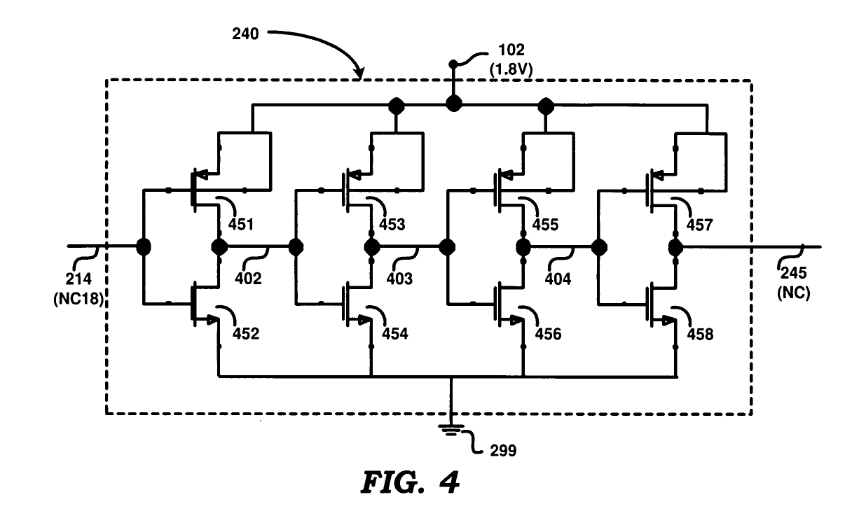

FIG. 4 is a circuit diagram illustrating the details of driver block 240 in an embodiment of the present invention. Driver block 240 is shown containing PMOS 451, 453, 455 and 457, and NMOS 452, 454, 456 and 458. Each pair of PMOS and NMOS transistor (e.g., PMOS 451 and NMOS 452) forms a buffer inverter stage, providing a corresponding output. Thus, the pair PMOS 451/NMOS 452 provides an inverted output 402 of signal 214 (NC18), the pair PMOS 453/NMOS 454 provides an inverted output 403 of signal 402, the pair PMOS 455/NMOS 456 provides an inverted output 404 of signal 403, and the pair PMOS 457/NMOS 458 provides an inverted output 245 (NC) of signal 404. Output NC18 of level-shifter 210 is provided to the first inverter stage causes (buffered) output NC (245) to be generated with the same logic level.

In the example embodiment, when input 123 is at logic high, NC18 is at logic low (as noted above with respect to level-shifter 210 of FIG. 2), and therefore node NC is also at logic low (0V). As a result, DENMOS 255 is off. From the description above, when input 123 is at logic high, DEPMOS 250 is on. As a result, output node 138 is at logic high (3.3V), as desired.

When input 123 is at logic low, DEPMOS 250 is off, DENMOS 255 is on, and output node 138 is at logic low (0V). All components of driver block 240 are fabricated using a 1.8V (lower voltage) process. The buffer (delay) stages are provided to minimize timing skew between signals PC and NC. Although a total of four buffer inverter stages are shown in FIG. 4, in general any even number of stages may be used instead.

From the foregoing description, it may be appreciated that driver blocks 230 and 240 control the operation of output transistors 250 and 255 to generate the desired logic level with a swing of 0-3.3V (high voltage swing) at output node 138.

It may be also be observed from the circuits of FIGS. 3 and 4 that there are no current paths in the steady states (i.e., zero static current consumption) of output signal 138 (corresponding to portions 180 and 185 of the waveform of FIG. 1B). For example, when a bias voltage of 1.8 Volts is generated on node PC 235, there is no current flowing through the path from PC 235 through transistors 359 and 360 to power supply 102 since node PC 235 is connected to the gate terminals (which do not pass current) of transistors 355 and 362, while transistor 358 is off. Similar observations can be made with respect to biasing of the remaining transistors 351, 352, 353, 364, 363, 354, 356, 357 and 361. Further, it may also be observed that no current flows between the power supply terminals 102 and 103. Thus, there are no static current paths between any of reference potentials 102, 103 and 299 (marked as ground terminal in FIG. 2).

Thus, output block 130 may be implemented with minimal (or zero) static current consumption and using a lower voltage process (1.8V process), and provides higher-swing output signals (0-3.3V). It is noted that level shifter 210 and PMOS nwell bias generator 220 may be implemented with minimal or zero static current consumption, using techniques well-known in the relevant arts.

As noted above, output block 230 may be configured (via) MODE18 signal (202) to provide output 138 with a swing of 0-1.8V (1.8V mode of operation) also, as briefly described next.

When 1.8V mode of operation is desired, 1.8V power supply is provided on path 103. Signal MODE18 (202) is at 1.8V. As a result, PMOS transistors 357 and 360 are off, while DENMOS 354 and 361 are on. NMOS transistors 352 and 363 are on, since they are enabled by the 1.8V at their gate terminals. Transistors 357, 360, 356, 359 do not play any role in influencing the operation of the circuit of FIG. 3 in the 1.8V mode of operation.

When PC18=0 and PCZ18=1.8V (corresponding to input 123 of FIG. 2 being at logic high), NMOS 353 is switched on, and pulls node PC to 0V (ground) through DENMOS 361 (which is on as noted above). Thus, output transistor DEPMOS 250 (FIG. 2) is on. With respect to FIG. 4, since NC18 is at logic zero (corresponding to input 123 of FIG. 2 being at logic high), node NC is also at logic 0 (0V), and output transistor DENMOS 255 (FIG. 2) is off. Thus, output node 138 provides 1.8V (from power supply 103 which receives 1.8V in the 1.8V mode of operation).

Continuing with the description of FIG. 3 in the 1.8V mode of operation, a 0V at node PC turns on PMOS 355, thereby causing node PCZ to have a voltage of 1.8V. As a result, PMOS 358 is switched off.

When PC18 switches from 0 to 1.8V, and PCZ18 switches from 1.8V to 0V (corresponding to input 123 of FIG. 2 changing from logic high to logic low), NMOS 364 is switched on, and pulls node PCZ to 0 through DENMOS 354 (which is on). As a result, PMOS 358 is switched on, thereby causing a voltage of 1.8V to be provided at node PC. A 1.8V at node PC turns off PMOS 355. With node PC being at 1.8V, DEPMOS 250 (FIG. 2) is turned off. With respect to FIG. 4, since NC18 is at logic one (corresponding to input 123 of FIG. 2 being at logic zero), node NC is also at logic 1 (1.8V), and output transistor DENMOS 255 (FIG. 2) is turned on. Thus, output node 138 is at logic 0 (0V).

It is noted that in the 1.8V mode of operation the supply voltages on paths 102 and 103 are both equal to 1.8V, and hence there are no reliability issues for any of the transistors in the circuit of FIG. 3. Again, it may be observed that no static current is drawn between power and ground reference potentials connected to output block 130 when output signal 138 is in a steady state.

In the embodiment of output block 130 described above with respect to FIGS. 2, 3 and 4, when power supply voltages 3.3V and 1.8V (used in the 3.3V mode of operation) vary widely from their desired values (of 3.3V and 1.8V), the operation of the driver block 230 may be less then optimal. For example, assuming a 10 percent variation in both the 1.8V and 3.3V power supplies, a scenario may exist wherein power supply 3.3V actually has a voltage of 2.97V (lower end of the 10 percent variation range), and power supply 1.8V actually has a voltage of 1.98V (upper end of the 10 percent variation range).

In such a scenario, it may be appreciated that PMOS 355 and 358 will be provided with a poor drive (source-gate potential difference being less than 1.5V). This may result in large variations in the voltage produced at node PC. Further wide variations in the two power supply voltages may cause a mismatch in the voltage swings at nodes PC and NC, with node PC potentially seeing wider voltage variations than node NC, thereby potentially rendering the rise/fall times (transient performance) of output signal 138 unpredictable or with wide variations/delays.

Specifically, both the PC and NC signals may be sensitive to the 1.8V power supply value. A higher value of this power supply may cause a stronger pull-down strength and a weaker pull-up strength at output node 138, and vice versa. An embodiment of an output block that does not exhibit (or at least minimizes) the drawbacks noted above is accordingly described next.

### 5. Improved Output Block

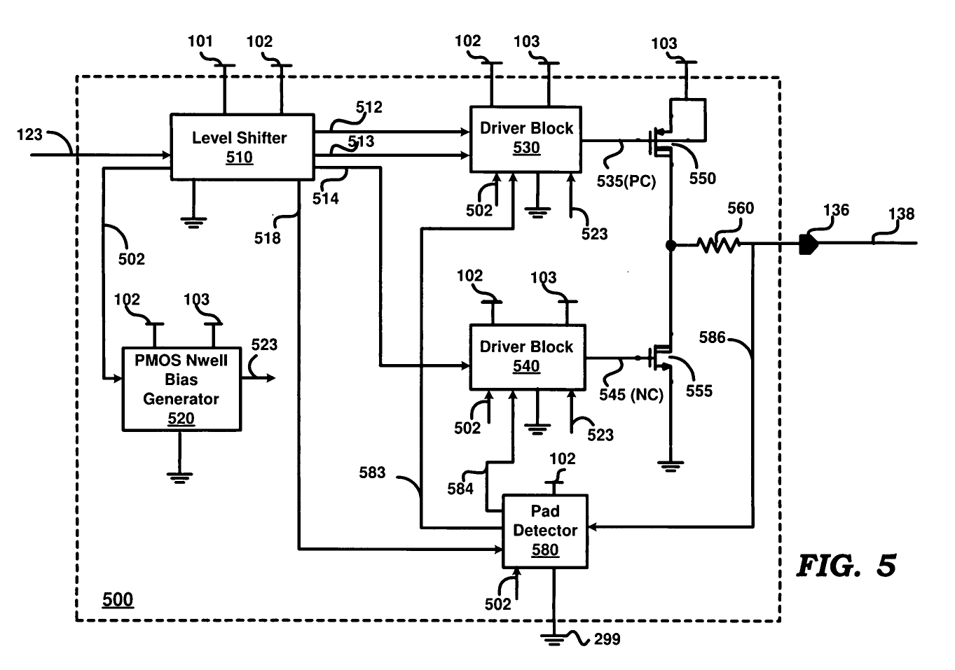

FIG. 5 is a block diagram of an output block in another embodiment of the present invention. Output block 500 is shown containing level shifter 510, PMOS nwell bias generator 520, driver blocks 530 and 540, DEPMOS 550, DENMOS 555, resistor 560 and pad detector 580. In the following description nodes/voltages pad 136 and output signal 138 (containing the same signal/voltage) are used interchangeably.

Level shifter 510 and PMOS nwell bias generator 520 are implemented (and operate) similar to level shifter 210 and PMOS nwell bias generator 220 of FIG. 2, and their description is not repeated here in the interest of conciseness. Similarly, signals on paths 512, 513, 514, 502 and 523 correspond (and operate similar to) respectively to signals on paths 212, 213, 214, 202 and 223 of FIG. 2. It is noted that signal 502 (MODE18 signal) is provided to each of driver blocks 530 and 540 and pad detector 580. PMOS nwell bias signal 523 is provided to each of driver blocks 530 and 540. Resistor 560 corresponds to resistor 260 of FIG. 2.

Driver blocks 530 and 540 respectively control on/off operation of DEPMOS 550 and DENMOS 555, and are designed to overcome the drawbacks noted with respect to the embodiment described with respect to FIGS. 3 and 4 (i.e., improvements that help achieve good performance irrespective of 1.8V (102) power supply voltage variations in the 3.3V mode of operation). It is noted that driver blocks 530 and 540 operate together in a complementary manner, driving nodes PC (535) and NC (545) substantially simultaneously to with the required voltages to provide output signal 138.

As described in detail below, each of driver blocks 530 and 540 uses an internally generated (and precise) reference voltage when operating to cause a transition (logic high-to-low or logic low-to-high) in output signal 138, but use the 1.8V power supply, once the transition is complete. As a result, the transient performance of output signal 138 is rendered independent of any deviations/variations in the 1.8V power supply.

Each of driver blocks 530 and 540 receives signals via respective paths 583 and 584 to turn on or off corresponding circuit portions contained within them to enable the transient performance noted above, as described in detail below.

Pad detector 580 receives a signal (voltage) on pad 136 (or path 138), and a signal (voltage) corresponding to (or same as) input signal 123 via path 518 from level shifter block 510. Based on the two received signals, pad detector 580 generates output signals 583 and 584 to turn off corresponding circuit portions in the respective driver blocks, as noted above.

Thus, in the embodiment, switching of the output signal 138 is performed using a precise internal reference (or multiple precise references), thereby improving the transient performance of output 138. Further, the internal reference is used only for the duration of transition of output 138. Therefore, any static current consumption by the internal reference is minimal.

The internal details of driver block 530 are described next with respect to an embodiment of the present invention.

### 6. Improved Driver Block

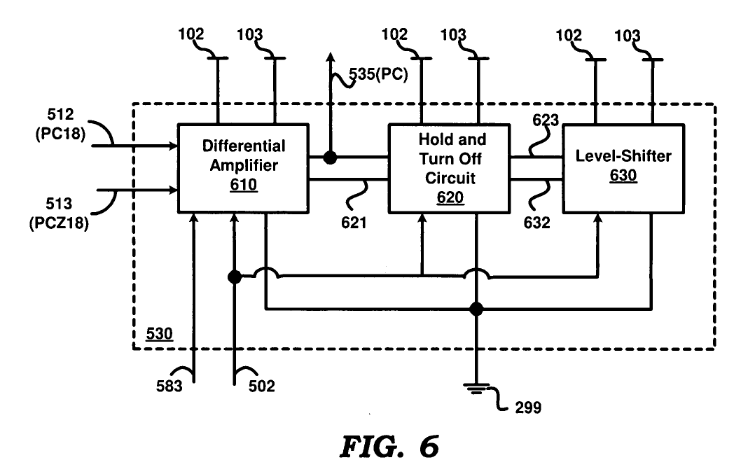

FIG. 6 is a block diagram of an improved driver block in an embodiment of the present invention. Driver block 530 is shown containing differential amplifier 610, hold-and-turn-off circuit 620 and level-shifter 630. The blocks are described briefly below.

Differential amplifier 610 receives data outputs of level shifter 510 (FIG. 5) as well as signal 583 from pad detector 580 (FIG. 5), and operates to pull node PC (535) to 0.5 times voltage of power supply 103 in 3.3V mode of operation, and to 0V in the 1.8V mode of operation.

In general, differential amplifier 610 operates to quickly change the state of PC (and thereby of output node 138) till signal 583 (from pad detector 580) switches the differential amplifier off.

Thus, differential amplifier 610 is switched on when a transition at PC is needed (corresponding to a transition at output node 138), and turned off (via signal 583) once pad detector determines that the output voltage at pad 136 (or equivalently at output node 138) has reached a high enough value (greater than a high threshold).

As described below, differential amplifier 610 uses an internally generated (precision) reference during the process of causing a transition at node PC. As a result (and in contrast to the previous embodiment described above), the transient performance of the rise operation is independent of the VDDS18 voltage, since most of the transition is governed by the diff amp which is VDDS based and only DC states are restored by VDDS18.

Hold-and-turn-off circuit 620 maintains node PC at a constant desired level once differential amplifier 610 is shut off. Thus, once the logic level at output node 138 has been changed, hold-and-turn-off circuit 620 sustains the final (steady-state) voltage. As described below, hold-and-turn-off circuit 620 is implemented to draw zero static current. Hold-and-turn-off circuit 620 receives signals PC18 and PCZ18 via path 621.

Level-shifter 630 generates signals on paths 623, and gets PC18 and PCZ18 signals via path 632 required for operation of hold-and-turn-off circuit 620, and is described in detail below.

The internal details of differential amplifier 610 are described next with respect to an embodiment of the present invention.

### 7. Differential Amplifier Used in a Driver Block

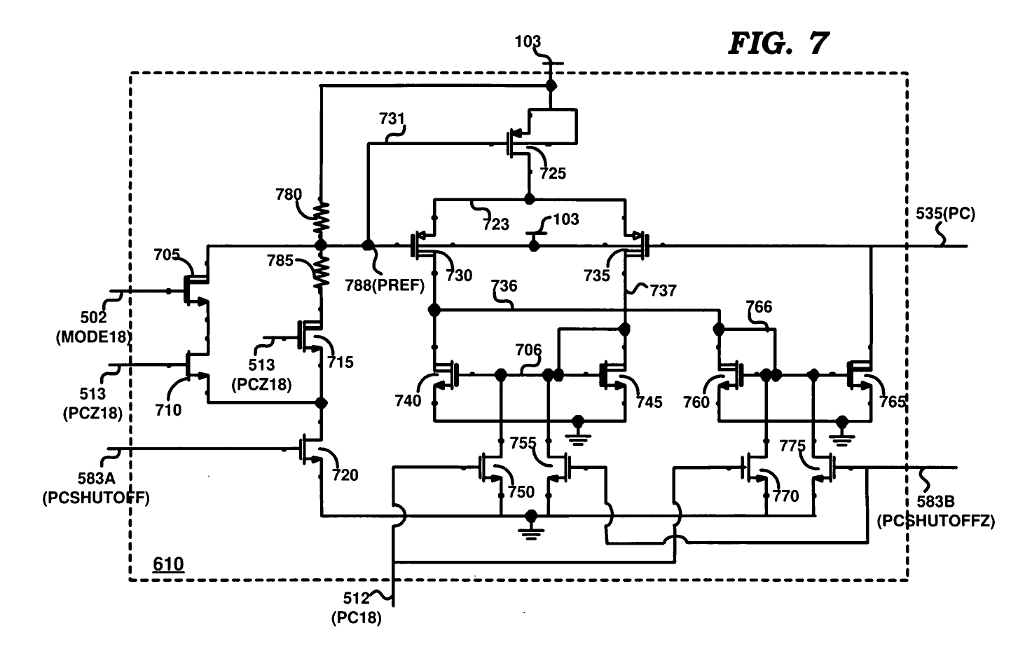

FIG. 7 is a circuit diagram illustrating the internal details of a differential amplifier used in driver block 530 in an embodiment of the present invention. Differential amplifier 610 is shown containing DEPMOS transistors 730 and 735, DENMOS transistors 705, 715, 740, 745, 760 and 765, PMOS 725, NMOS 710, 720, 750, 755, 770 and 775, and resistors 780 and 785. Resistors 780 and 785 are equal valued resistors, and operate to generate an internal (precision) reference voltage (PREF) equal half of the voltage of power supply 103 when transistors 715 and 720 are on.

It is noted that DEPMOS and DENMOS transistors of FIG. 7 (as well as those in other Figures referred to in this document) are fabricated using a 1.8V process, but having a drain-extended construction can reliably withstand voltages of greater than 1.8V (e.g., 3.3V) across their respective gate-to-drain and drain-to-source terminals.

Signals 583A (PCSHUTOFF) and 583B (PCSHUTOFFZ) are complementary binary signals received from pad detector 580 (FIG. 5) are deemed to be contained in path 583 (FIGS. 5 and 6). When voltage on pad 136 (path 138) is logic low, signal PCSHUTOFF is a logic high and PCSHUTOFFZ is a logic low. Logic high voltage of these signals is 1.8V (102 supply voltage level) and logic low is 0V. The operation of the circuit of FIG. 7 in the 3.3V mode is described next.

To illustrate the operation of the circuit of FIG. 7, it is assumed that input data 123 (FIG. 2) was at logic low, with signals PCZ18 and PC18 consequently being at logic low and logic high respectively (pad 136 being at logic low). Since PCZ18 is low, transistor 710 is off. Assuming that input data 123 changes to logic 1, signals PC18 and PCZ18 would respectively change to logic low and logic high. However, pad 136 is as yet at logic low, with node PCSHUTOFF being at 1.8V. Pad detector 580 (FIG. 5) senses the voltage on pad 136, and generates signal PCSHUTOFF at logic high, and PCSHUTOFFZ at logic low.

As a consequence of PCSHUTOFF going high (signal PCZ18 also being high), transistors 715 and 720 are switched on. As a result voltage divider network formed by resistors 780 and 785 generate a voltage equal to 1.65V (half of power supply 103, assumed 3.3V in the 3.3V mode of operation). As a result, transistor 725 is switched on, and the differential amplifier structure formed by transistors 730 and 735 is turned on (operational).

Since signals PC18 and PCSHUTOFFZ are each logic low, transistors 750, 755, 770 and 775 are off. Since node PC still at 3.3V (as noted above), transistor 735 is in an off state. However, transistor 730 is on due to the 1.65V at node PREF. As a result, a current flows via path 736 through transistors 730 and 725 (from power supply 103) into the ratioed current mirror pair formed by transistors 760 and 765 (the current mirror pair being termed ratioed since, for example, transistor 765 may be built using multiple instances of transistors similar to 760, for e.g., five transistors of similar dimension as 760 would form transistor 765). Specifically, biasing path 766 switches on transistor 765, and the ratioed current mirror structure of transistors 760 and 765 causes the same current to flow through each of these transistors

Due to the switching on of transistor 765, voltage at node PC starts falling from 3.3V. Transistor 735 may switch on when node PCSHUTOFF(535) falls sufficiently low. Switching on of transistor 735 switches on current mirror pair formed by transistors 740 and 745, and currents start flowing through paths 723 and 737 respectively to ground. When the voltage at node PC reaches 1.65V (i.e., equal to the voltage at internal reference node PREF), current on each of paths 723 and 737 are equal and a steady state is reached, in which no current flows though 736, with the voltage at node PC remaining at 1.65V (as long as the circuit of FIG. 7 is operational/on).

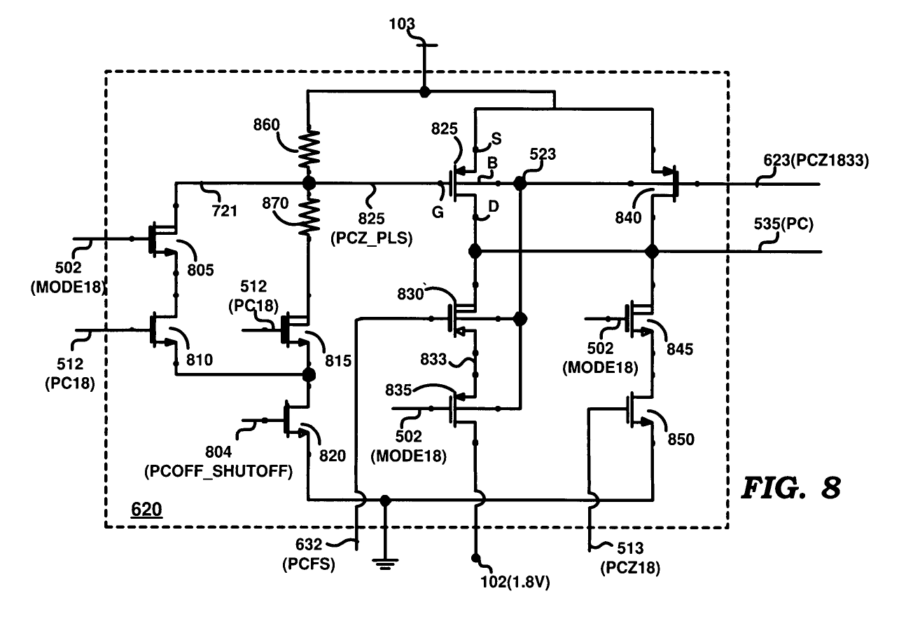

A 1.65 V at node PC causes DEPMOS 550 to be switched on. It is noted that the operation of driver block 540 (of FIG. 5) (internal details illustrated with respect to FIGS. 8, 9 and 10 below) for the example scenario described above would cause node NC also to have a logic high, thereby switching off DENMOS 555. As a result, a voltage of 3.3V (from power supply 103) is provided on pad 136 and output signal 138, i.e., a logic high is provided at output node 138 in response to a logic high at input 123.

Once the voltage at pad 136 has risen above a (predetermined) high threshold value (close to 3.3V), pad detector 580 (FIG. 5) causes PCSHUTOFF to go to logic low (and PCSHUTOFFZ to logic high). A logic low level of signal PCSHUTOFFZ switches of transistor 720, and the path from resistors 780/785 to ground terminal is opened. As a result, the voltage at node PREF goes to 3.3V (from power supply 103 via resistor 780), thereby switching off transistor 725. Further, the logic low of signal PCSHUTOFFZ causes node 706 to be pulled to ground, and the circuit of FIG. 7 does not further influence or control the voltage at node PC (which is currently 1.65V). From the description above, it may be appreciated that pad detector 580 may be viewed as determining when (time instance) transitions of output signal 138 are to be initiated and ended, and as controlling driver block 530 to perform the corresponding transitions.

Substantially simultaneously, node PC is taken to power supply 102 (nominal/desired voltage 1.8V, but which may have an actual voltage slightly different from 1.8V), and held at that voltage by hold-and-turn-off circuit 620, described below.

Thus, differential amplifier 610 operates only when a transition from logic low to logic high (corresponding to the rising edge portion 182 of the waveform of FIG. 1B) in output node 138 is required, and is switched off once the transition is complete. Therefore, the static current drawn by resistor divider 780/785 is minimal, and is restricted only for the duration of the transition. Further, since a precision internal reference is used to accomplish the transition, the transient performance (noted above) of output signal 138 is rendered predictable and independent of power supply variations, as desired. The operation of the circuit of FIG. 7 in the 1.8V mode is briefly noted next.

In the 1.8V mode of operation signal power supply 103 is connected to a 1.8V supply. Signal MODE18 (502) has a voltage 1.8V, which turns on transistor 705. The operation of the circuit of FIG. 7 in the 1.8V mode is similar to that in the 3.3V mode of operation, expect that when the differential amplifier is operational (on), resistor 785 is bypassed and node PREF is taken to 0V (instead of 1.65V in the 3.3V mode). This enables PC to fall to 0V till the amplifier reaches steady state. Similar to the 3.3V mode, once pad 136 reaches high threshold (close to 1.8V) the differential amplifier is turned off and PC is maintained at 0V by hold-and-turn-off circuit 620.

The description is continued with respect to the internal details of hold-and-turn-off circuit 620 in an embodiment of the present invention.

### 8. Hold-and-Turn-Off Circuit

FIG. 8 is a circuit diagram illustrating the internal details of a hold-and-turn-off circuit in an embodiment of the present invention. Hold-and-turn-off circuit 620 is shown containing DEPMOS 830, DENMOS 805, 815 and 845, PMOS 825, 835 and 840, NMOS 810, 820 and 850, and resistors 860 and 870.

Gate, source, bulk and drain terminals of PMOS 825 are marked in FIG. 8 as G, S, B and D respectively. Corresponding terminals (where shown) of other transistors have similar meanings. Signal 523 (generated by PMOS nwell bias generator 520) is provided to the bulk terminals of transistors 825, 830, 835 and 840 to bias NWELLs of these transistors to a potential that is higher of the two voltages 1.8V (on path 102) and 3.3V (on path 103) and minimizes latch-up issues during power-up of the circuit. The operation of the circuit of FIG. 8 is described next.

Node 804 receives a signal (PCOFF_SHUTOFF generated internally), which is a 1.8V-level signal (102 supply voltage level), which is a buffered version of signal PCZ18 (513), generated by a delay generator circuit (not shown) that generates delay only for logic high to logic low transition at PCZ18. When PCZ18 transitions form logic low to logic high PCOFF_SHUTOFF transitions from logic low to logic high with minimal delay, but when PCZ18 transitions from logic high to logic low, PCOFF_SHUTOFF transitions from logic high to logic low after a pre-determined delay.

Signal PCZ1833 (623) is generated by level-shifter 630, and has a range from 1.8V (corresponding to logic low) to 3.3V (corresponding to logic high). Signal PCFS (632) provided by level-shifter 630 (FIG. 6) has a swing range of 3.3V (corresponding to logic high) to 0V (corresponding to logic low). Signals PCZ1833 (623) and PCFS (632) are complementary with respect to each other in terms of logic levels.

In the 3.3V mode of operation, MODE18 is at logic low, which turns off transistors 805 and 845. Transistor 835 is always on in the 3.3V mode, and a voltage of 1.8V is provided at node 833. As described below, signal PCFS (632) is generated with a logic level low (e.g., 0V) to maintain/hold the value of node PC (535) at voltage 102 (1.8V nominal) once the transition of the voltage at node PC has been accomplished by differential amplifier 610 (FIG. 7). Thus, for example, once node PC (535) falls from 3.3V to 1.65V (as described above with respect to FIG. 7), signal PCFS (632) is generated (by level shifter 630) at a logic low level. PCZ1833 (623) is at 3.3V for the above condition.

As a result of PCFS (632) being logic low, transistor 830 is turned on, and voltage 102 is provided (from power supply 102, via switched-on transistors 835 and 830) at node PC (535). Thus, the operation of hold-and-turn-off circuit 620 holds (maintains) the steady state logic level voltage at node PC (535) once transition of PC is effected by differential amplifier 610. Thus, the corresponding steady state (portion 185 in FIG. 1B) of output signal 138 does not result in static current consumption.

As noted above, voltage 102 may be different from 1.8V due to power supply variations. Assuming, for example, the upper limit of such variation as causing voltage 102 to have a value of 1.98V, the operation of hold-and-turn-off circuit 620 as noted above would cause 1.98V to be provided at node PC. Such a voltage level is still good enough to maintain DEPMOS 550 in an on condition, and hence the deviation in the value of power supply 102 does not adversely affect output signal 138 in the steady state.

When node PC (535) is required to transition from voltage 102 to voltage 103 (corresponding to the requirement of output node 138 to transition from 3.3V to 0V, i.e., fall transition 187 of FIG. 1B), PCZ18 goes to 0V and PC18 goes to 1.8V (102 power supply level). As a result, transistors 810, 815 and 820 are switched on, and resistors 860 and 870 form a voltage divider network and cause a voltage of 0.5 times voltage 103 (1.65V assuming power supply 103 provides exactly 3.3V) to be provided on node 825 (PCZ_PLS). As a result, transistor 825 is switched on quickly, and node PC (535) is thus quickly taken to voltage 103 (3.3V nominal), thereby quickly turning off DEPMOS 550, causing output signal 138 also to quickly switch to logic low (it is assumed that driver block 540 causes node NC also to switch to logic high in a corresponding manner). PCZ1833 (623) is at 3.3V for the above condition.

PCOFF_SHUTOFF (804) is switched to logic low after a predetermined duration. As a result, transistors 820 and 825 are switched off.

Signal PCZ1833 (623) is substantially simultaneously switched to voltage 102, thereby switching on transistor 840, and maintains node PC (535) at 3.3V.

It may be appreciated that the voltage divider network formed by resistors 860 and 870 operates to provide a reference voltage independent of power supply 102 (1.8V nominal) to accomplish the transition at node PC (535), and the transient performance of output signal 138 (for the 3.3V to 0V transition—logic high to logic low) is rendered predictable and independent of power supply variations in the 3.3V mode of operation, as desired. Further, once the transition is effected, the voltage divider network does not cause static current consumption, and the corresponding portions of circuit of FIG. 8 as described above hold/maintain node PC (535) at the steady state. Thus, the corresponding steady state (portion 180 in FIG. 1B) of output signal 138 does not result in static current consumption. The 1.8V mode of operation of the circuit of FIG. 8 is briefly described next.

In the 1.8V Mode of operation, power supply 103 receives 1.8V, signal MODE18 equals voltage 102, and transistor 835 is off. Transistors 830 and 835 do not play any role in this mode of operation. To cause a fall transition at PC (535), PCZ18 (513) switches from 0 to 1.8V turning on transistor 850. Since transistor 845 is on due to MODE18 being 1.8V, node PC falls to 0. Signal PCZ1833 (623) swings from 0 to 1.8V turning off transistor 840.

When node PC needs to rise to voltage 103, the operation is similar to as in the 3.3V mode of operation (described above), with the exception that transistors 805 and 810 by-pass (shunt) resistor 870, and pull node PCZ_PLS (825) to 0V. As a result, node PC (535) is pulled to voltage 103 through transistor 825. Signal PCZ1833 swings from 1.8V to 0V and holds (maintains) node PC (535) to voltage 103 through transistor 840.

The description is continued with an illustration of the internal details of level shifter 630.

### 9. Level Shifter

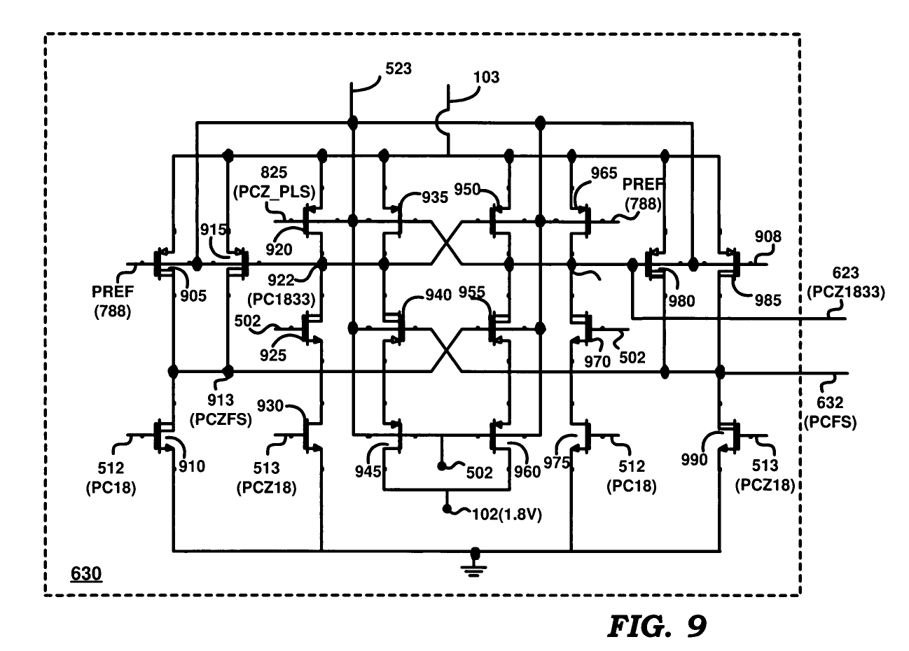

FIG. 9 is a circuit diagram illustrating the internal details of a level shifter of a driver block in an embodiment of the present invention. Level shifter 630 is shown containing DEPMOS 905, 915, 940, 955, 980 and 985, DENMOS 910, 925, 970 and 990, PMOS 920, 935, 945, 950, 960 and 965, and NMOS 930 and 975. The operation of level shifter 630 is described briefly below.

As noted above, level-shifter 630 generates signals PCFS (632) and PCZ1833 (623) used in hold-and-turn-off circuit 620 described above. The operation of the circuit of FIG. 9 is substantially similar to that of the circuit of FIG. 3 (described above), with some exceptions, as noted below.

The circuit of FIG. 9 has additional transistors in corresponding paths to enhance the performance of level shifter 630 when voltage 102 is higher than the nominal 1.8V voltage, and voltage 103 is lower than the nominal 3.3V voltage. Accordingly, transistors 905, 920, 965 and 985 are contained in addition to enhance the performance. The gate terminals of each of transistors 905, 920, 965 and 985 is pulsed by corresponding signals (as noted in FIG. 9) used in differential amplifier 610 and hold-and-turn-off circuit 620. Signals PREF (788) and PCZ_PLS (825) are generated from power supply 103, and equal 0.5 times voltage 103.

Driver block 540 is implemented using internal blocks similar and complementary to the internal blocks of driver block 530. In the interest of conciseness, a detailed description of the corresponding internal blocks of driver block 540 is not provided, and brief descriptions are instead provided below. The internal details of driver block 540 whose output NC (545) controls the gate terminal of DENMOS 555 (of FIG. 5) to switch on/off DENMOS 555 (as noted above) are described next.

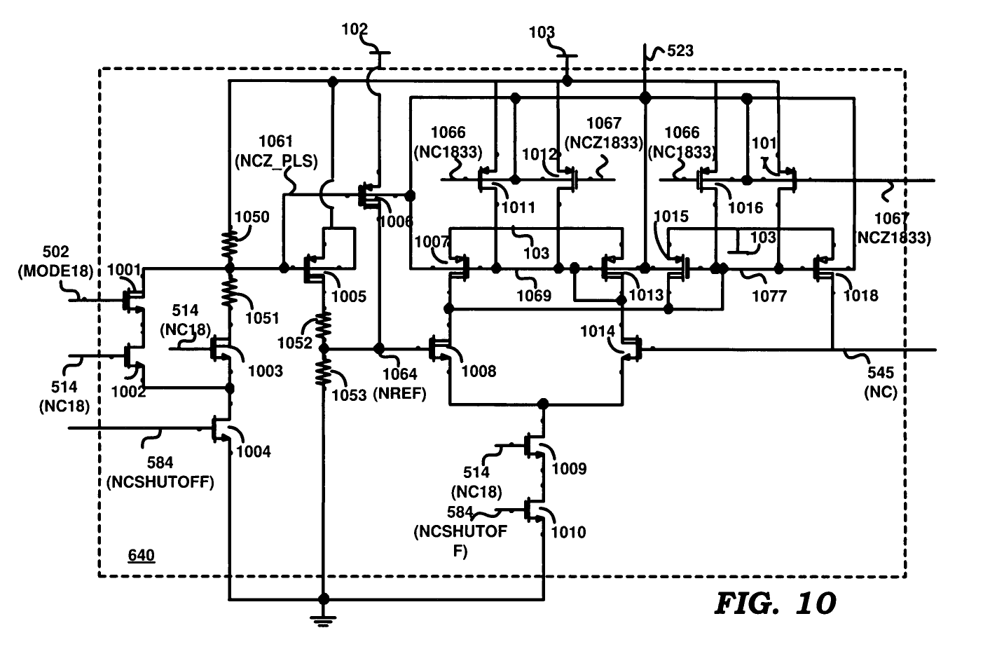

FIG. 10 is a circuit diagram of a differential amplifier (NC differential amplifier 640) used to realize a rise transition at node NC (545). NC differential amplifier 640 is shown containing DEPMOS 1005, 1006, 1007, 1013, 1015 and 1018, DENMOS 1001, 1003, 1008, and 1014, PMOS 1011, 1012, 1016 and 1017, NMOS 1002, 1004, 1009 and 1010, and resistors 1050, 1051, 1052 and 1053. The circuit of FIG. 10 is complementary to differential amplifier 610 of FIG. 7. Therefore, in the interest of conciseness a detailed description of the circuit is not provided, and only the following differences/exceptions are noted.

A reference voltage NREF (node 1064) is generated using signal at node NCZ_PLS (1061) to drive the gate terminal of transistor 1005. Two resistor divider pairs (1050/1051 and 1052/1053) are employed in the circuit of FIG. 10, as against only one (to generate PREF 788) FIG. 7. Transistor 1006 pulls node NREF (10640 to power supply voltage 102 in the 1.8V mode of operation. Two footer transistors 1010 and 1009 are used to turn on and turn off NC differential amplifier 640 with 1.8V-level signals (NC18 and NCSHUTOFF) applied at their respective gate terminals.

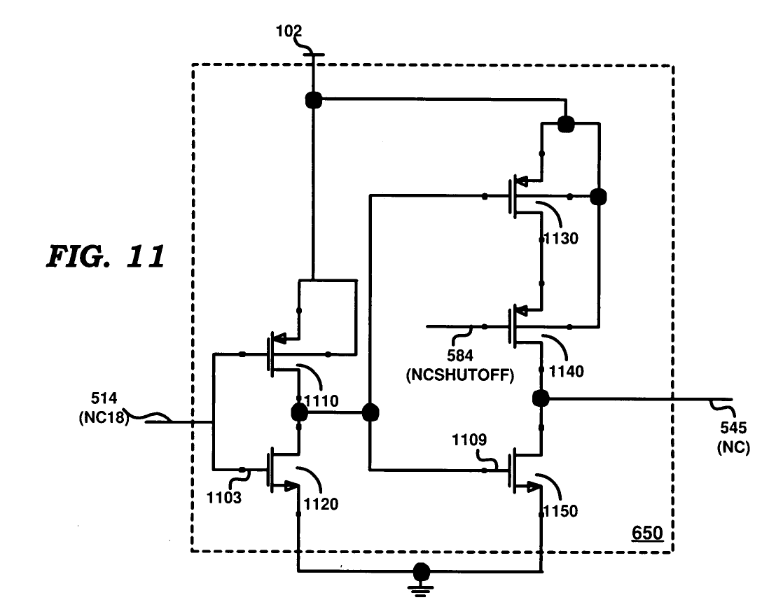

FIG. 11 is a circuit diagram of a hold and turn off circuit which restores node NC (545) to voltage 102 once signal NCSHUTOFF switches to 0 (i.e., pad 136 reaches a low enough voltage).

NC hold-and-turn-off circuit 650 is shown containing PMOS 1110, 1130 and 1140, and NMOS 1120 and 1150. To realize a fall transition at node NC (545), signal NC18 (514) switches from voltage 102 to 0V, which pulls node NC (545) to 0V through transistor 1150.

Though not shown driver block 540 also contains a level-shifter circuit which generates NC1833 and NCZ1833 signals used to hold the corresponding internal nodes of NC differential amplifier (640) internal nodes to known states, and is implemented in a manner similar to level-shifter 630 of FIG. 9.

The description is continued with an illustration of the internal details of a pad detector circuit used in an output block in an embodiment of the present invention.

### 10. Pad Logic State Detector Feedback Circuit

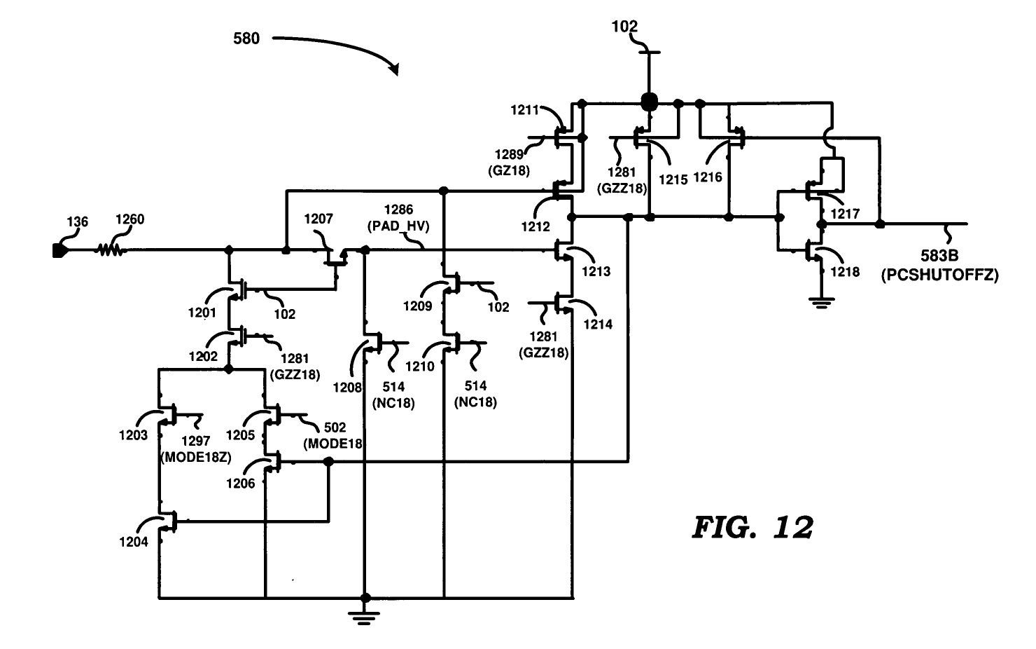

FIG. 12 is a circuit diagram illustrating a portion of pad detector circuit 580 (also referred to in this document as pad logic state detector feedback circuit) of FIG. 5.The circuit shown in FIG. 12 generates signal PCSHUTOFF (583A) (PAD High threshold signal that is used to shut off differential amplifier 610 (FIG. 7). The circuit of FIG. 12 is shown containing transistors 1201-1218, and resistor 1260. Signal MODEZ18 (1297) is complementary to signal MODE18 (502).

Resistor 1260 and transistors 1201, 1202, 1203, 1204, 1205 and 1206 form a potential divider network of the voltage at pad 136. Different switching thresholds are needed for 3.3V and 1.8V mode of operation, so transistors 1203 and 1204 operate during 3.3V mode of operation and transistors 1205 and 1206 operate during 1.8V mode of operation. Node PAD_HV (1286) swings from 0V to (voltage 102—Vt) for a swing of 0 to voltage 103 at pad 136, wherein Vt is the threshold voltage. Pad 136 is directly connected to the gate terminal of transistor 1212 to avoid crowbar current when pad 136 (output path 138) reaches logic-high state.

During normal mode of operation signal GZ18 (1289) equals 0V, and signal GZZ18 (1281) equals voltage 102, wherein signals GZ18 and GZZ18 are complementary signals. When pad 136 is to be tri-stated, signal GZ18 (1289) equals voltage 102, and signal GZZ18 (1281) equals 0V.

When voltage at pad 136 is 0V, node PAD_HV (1286) is also at 0V, which causes the output of first stage comprising transistors 1211, 1212, 1213, 1214 to be voltage 102. As a result, the pad voltage divider circuit (noted above) is turned on either through transistors 1201, 1202, 1203 and 1204, or transistors 1201, 1202, 1205 and 1206. Signal PCSHUTOFFZ (583B) would be held at 0V.

During a rise transition at pad 136 (caused by DEPMOS 550), voltage at node PAD_HV (1286) rises depending on the voltage division provided by the pad voltage divider circuit noted above. When voltage at pad 136 exceeds (voltage 102—Vtp), transistor 1212 is cut off. At this voltage node PAD_HV may not have reached a high enough voltage to turn on transistor 1213. Latch connected transistor 1216 restores the state at the output of the first stage.

When voltage at node PAD_HV reaches a high enough value, transistor 1213 is switched on. Transistor 1213 has to overcome the strength of transistor 1216 to trip the output of the first stage comprising transistors 1211, 1212, 1213, 1214 to 0V This turns the pad voltage divider circuit off, and node PAD_HV rises to (voltage 102—Vt). Signal PCSHUTOFFZ (583B) trips to voltage 102. The pad voltage detector is designed in such a way that the pad voltage at which signal PCSHUTOFFZ (583B) trips is very high (approx 2.8V for a 3.3V supply). Current drawn form pad 136 during this operation is very small and does not affect the rise time at pad 136.

When voltage at pad 136 starts falling, signal NC18 switches from 0V to voltage 102. This pulls PCSHUTOFF and gate of transistor 1212 low quickly through. and trips PCSHUTOFFZ to 0V. Current drawn from pad 136 during this operation is very small and does not affect the fall time at pad 136. A similar approach and circuit may be followed and implemented to generate signal NCSHUTOFF (584).

Again, it may be observed with respect to output block 500 described in detail above, that no static current is drawn (between any of multiple reference potentials such as power, ground etc., connected to output block 500) when output signal 138 is in a steady state.

### 11. Conclusion

While various embodiments of the present invention have been described above, it should be understood that they have been presented by way of example only, and not limitation. Thus, the breadth and scope of the present invention should not be limited by any of the above-described embodiments, but should be defined only in accordance with the following claims and their equivalents.

What is claimed is:

1. An output block to receive an input signal with a first voltage swing and generate an output signal with a second voltage swing, wherein said second voltage swing is greater than said first voltage swing, said output block comprising:
a first transistor and a second transistor operating as an inverter coupled between a first reference potential and a second reference potential having a potential difference substantially equaling said second voltage swing, said inverter receiving a first control signal and a second control signal and providing said output signal with said second voltage swing;
a first driver block coupled to receive said input signal and to switch on/off said first transistor by generating said first control signal; and
a second driver block coupled to receive said input signal and to switch on/off said second transistor by generating said second control signal,
wherein said first driver block contains a first plurality of transistors and said second driver block contains a second plurality of transistors,
wherein no closed path exists due to any of said first plurality of transistors and said second plurality of transistors between said first reference potential and said second reference potential when said output signal is in a steady state.

2. The output block of claim 1, further comprising a third reference potential which enables said output block to optionally provide said output signal with a corresponding voltage swing, wherein no closed path exists due to any of said first plurality of transistors and said second plurality of transistors between said first reference potential and said third reference potential when said output signal is in a steady state.

3. The output block of claim 2, further comprising a first level shifter to receive said input signal and to generate a plurality of level shifted signals, wherein each of said plurality of level shifted signals has a voltage swing greater than said first voltage swing.

4. The output block of claim 3, wherein said plurality of level shifted signals include a first level shifted signal and a second level shifted signal, wherein said first level shifted signal is a complement of said second level shifted signal, wherein said first driver block comprises:
a first transistor with a gate terminal coupled to receive said first level shifted signal and with a first current terminal coupled to said second reference potential;
a second transistor with a gate terminal coupled to receive said second level shifted signal and with a first current terminal coupled to said second reference potential;
a third transistor with a gate terminal coupled to receive said second reference potential and with a first current terminal coupled to a second current terminal of said first transistor;
a fourth transistor with a gate terminal coupled to receive said second reference potential and with a first current terminal coupled to a second current terminal of said second transistor;
a fifth transistor with a first current terminal coupled to said first reference potential and a second current terminal coupled to a second current terminal of said third transistor;
a sixth transistor with a first current terminal coupled to said first reference potential and a second current terminal coupled to a second current terminal of said fourth transistor;
a seventh transistor with a first current terminal coupled to said first reference potential and a second current terminal coupled to a gate terminal of said fifth transistor;
a eighth transistor with a first current terminal coupled to said first reference potential and a second current terminal coupled to a gate terminal of said sixth transistor and a gate terminal of said seventh transistor, wherein a gate terminal of said eighth transistor is coupled to said second current terminal of said seventh transistor;
a ninth transistor with a first current terminal coupled to said gate terminal of said fifth transistor, and a gate terminal coupled to said second current terminal of said fourth transistor;
a tenth transistor with first current terminal coupled to said gate terminal of said sixth transistor, and a gate terminal coupled to said second current terminal of said third transistor;
an eleventh transistor with a first current terminal coupled to a second current terminal of said ninth transistor and a second current terminal coupled to a third reference potential;
a twelfth transistor with a first current terminal coupled to a second current terminal of said tenth transistor and a second current terminal coupled to said third reference potential, and a gate terminal coupled to a gate terminal of said eleventh transistor;
a thirteenth transistor with a first current terminal coupled to said gate terminal of said fifth transistor, a second current terminal coupled to said second current terminal of said second transistor and a gate terminal coupled to said gate terminal of said eleventh transistor; and
a fourteenth transistor with a first current terminal coupled to said gate terminal of said sixth transistor, a second current terminal coupled to said second current terminal of said first transistor and a gate terminal coupled to said gate terminal of said eleventh transistor,
wherein said first control signal is presented at said gate terminal of said sixth transistor.

5. The output block of claim 4, wherein said plurality of level shifted signals further includes a third level shifted signal, wherein said second driver block comprises:
a sequence of even number of inverters connected in series and between said second reference potential and said third reference potential, wherein a first one of said even number inverters receives said third level shifted signal and last one of said four inverters provides said second control signal.

6. The output block of claim 5, wherein said gate terminal of each of said eleventh transistor and said twelfth transistor are coupled to a mode control signal, wherein said mode control signal specifies a first range for said second voltage swing when at a first logic level and a second range for said second voltage swing when at a second logic level.

7. The output block of claim 6, further comprising:
a PMOS nwell bias generator providing a bulk output signal having a voltage which is the greater of said first reference potential and said third reference potential,
wherein a bulk of each of said fifth transistor, sixth transistor, seventh transistor, eighth transistor, ninth transistor, tenth transistor, eleventh transistor, and twelfth transistors are coupled to said bulk output signal.

8. The output block of claim 2, further comprising a pad detector to determine a first time instance at which a transition of said output signal is to be initiated and a second time instance at which said transition is to end, and to control said each of said first driver block and said second driver block to perform corresponding transitions between said first time instance and said second time instance.

9. The output block of claim 8, wherein said plurality of level shifted signals include a first level shifted signal and a second level shifted signal, which are complements of each other, wherein said pad detector generates a first timing signal and a second timing signal, which are also complements of each other, wherein one state of said first timing signal indicates said first time instance and another state indicates said second time instance, wherein said first driver block comprises:
a differential amplifier receiving said first level shifted signal, said second level shifted signal, said first timing signal and said second timing signal, and generates a bias signal to cause a corresponding positive transition of said output signal, with the timing of said corresponding positive transition being determined by said first timing signal and said second timing signal, wherein said bias signal is generated only for the duration of said positive transition.

10. The output block of claim 9, wherein said first driver block further comprises:
a hold and turn off circuit to receive said first level shifted signal and said second level shifted signal and operates to cause a corresponding negative transition of said output signal as well as to maintain said steady state after each of said corresponding positive and negative transitions; and
a level shifter circuit to generate a pair of signals to support operation of said hold and turn-off circuit.

11. The output block of claim 9, wherein said plurality of level shifted signals include a third level shifted signal, wherein said pad detector generates a third timing signal, wherein one state of said third timing signal indicates said first time instance and another state indicates said second time instance, said output block further comprising a second driver block, said second driver block comprising:
a second differential amplifier receiving said third level shifted signal, said third timing signal, and generating a second bias signal to cause said corresponding positive transition, with the timing of said corresponding positive transition being determined by said third timing signal, wherein said second bias signal is generated only for the duration of said corresponding positive transition;
a second hold and turn off circuit to receive said third level shifted signal and to cause said corresponding negative transition and maintain said steady state after each of said corresponding positive and negative transitions; and
a second level shifter circuit to generate signals to support operation of said second hold and turn-off circuit.

12. A device comprising:
a core block to generate a digital signal with a first voltage swing; and
an output block to receive said digital signal with said first voltage swing and to generate an output signal with a second voltage swing, wherein said second voltage swing is greater than said first voltage swing, said output block comprising:
a first transistor and a second transistor operating as an inverter coupled between a first reference potential and a second reference potential having a potential difference substantially equaling said second voltage swing, said inverter receiving a first control signal and a second control signal and providing said output signal with said second voltage swing;
a first driver block coupled to receive said input signal and to switch on/off said first transistor by generating said first control signal; and
a second driver block coupled to receive said input signal and to switch on/off said second transistor by generating said second control signal,
wherein said first driver block contains a first plurality of transistors and said second driver block contains a second plurality of transistors,
wherein no closed path exists due to any of said first plurality of transistors and said second plurality of transistors between said first reference potential and said second reference potential when said output signal is in a steady state.

13. The device of claim 12, wherein said output block further comprises a third reference potential which enables said output block to optionally provide said output signal with a corresponding voltage swing, wherein no closed path exists due to any of said first plurality of transistors and said second plurality of transistors between said first reference potential and said third reference potential when said output signal is in a steady state.

14. The device of claim 13, wherein said output block further comprises a first level shifter to receive said input signal and to generate a plurality of level shifted signals, wherein each of said plurality of level shifted signals has a voltage swing greater than said first voltage swing.

15. The device of claim 14, wherein said plurality of level shifted signals include a first level shifted signal and a second level shifted signal, wherein said first level shifted signal is a complement of said second level shifted signal, wherein said first driver block comprises:
a first transistor with a gate terminal coupled to receive said first level shifted signal and with a first current terminal coupled to said second reference potential;
a second transistor with a gate terminal coupled to receive said second level shifted signal and with a first current terminal coupled to said second reference potential;
a third transistor with a gate terminal coupled to receive said second reference potential and with a first current terminal coupled to a second current terminal of said first transistor;
a fourth transistor with a gate terminal coupled to receive said second reference potential and with a first current terminal coupled to a second current terminal of said second transistor;
a fifth transistor with a first current terminal coupled to said first reference potential and a second current terminal coupled to a second current terminal of said third transistor;
a sixth transistor with a first current terminal coupled to said first reference potential and a second current terminal coupled to a second current terminal of said fourth transistor;
a seventh transistor with a first current terminal coupled to said first reference potential and a second current terminal coupled to a gate terminal of said fifth transistor;
a eighth transistor with a first current terminal coupled to said first reference potential and a second current terminal coupled to a gate terminal of said sixth transistor and a gate terminal of said seventh transistor, wherein a gate terminal of said eighth transistor is coupled to said second current terminal of said seventh transistor;
a ninth transistor with a first current terminal coupled to said gate terminal of said fifth transistor, and a gate terminal coupled to said second current terminal of said fourth transistor;
a tenth transistor with first current terminal coupled to said gate terminal of said sixth transistor, and a gate terminal coupled to said second current terminal of said third transistor;
an eleventh transistor with a first current terminal coupled to a second current terminal of said ninth transistor and a second current terminal coupled to a third reference potential;
a twelfth transistor with a first current terminal coupled to a second current terminal of said tenth transistor and a second current terminal coupled to said third reference potential, and a gate terminal coupled to a gate terminal of said eleventh transistor;
a thirteenth transistor with a first current terminal coupled to said gate terminal of said fifth transistor, a second current terminal coupled to said second current terminal of said second transistor and a gate terminal coupled to said gate terminal of said eleventh transistor; and
a fourteenth transistor with a first current terminal coupled to said gate terminal of said sixth transistor, a second current terminal coupled to said second current terminal of said first transistor and a gate terminal coupled to said gate terminal of said eleventh transistor,
wherein said first control signal is presented at said gate terminal of said sixth transistor.

16. The device of claim 15, wherein said plurality of level shifted signals further includes a third level shifted signal, wherein said second driver block comprises:
a sequence of even number of inverters connected in series and between said second reference potential and said third reference potential, wherein a first one of said even number inverters receives said third level shifted signal and last one of said four inverters provides said second control signal.

17. The device of claim 16, wherein said gate terminal of each of said eleventh transistor and said twelfth transistor are coupled to a mode control signal, wherein said mode control signal specifies a first range for said second voltage swing when at a first logic level and a second range for said second voltage swing when at a second logic level.

18. The device of claim 14, wherein said output block further comprises a pad detector to determine a first time instance at which a transition of said output signal is to be initiated and a second time instance at which said transition is to end, and to control said each of said first driver block and said second driver block to perform corresponding transitions between said first time instance and said second time instance.

19. The device of claim 18, wherein said plurality of level shifted signals include a first level shifted signal and a second level shifted signal, which are complements of each other, wherein said pad detector generates a first timing signal and a second timing signal, which are also complements of each other, wherein one state of said first timing signal indicates said first time instance and another state indicates said second time instance, wherein said first driver block comprises:
a differential amplifier receiving said first level shifted signal, said second level shifted signal, said first timing signal and said second timing signal, and generates a bias signal to cause a corresponding positive transition of said output signal, with the timing of said corresponding positive transition being determined by said first timing signal and said second timing signal, wherein said bias signal is generated only for the duration of said positive transition.

20. The device of claim 19, wherein said first driver block further comprises:
a hold and turn off circuit to receive said first level shifted signal and said second level shifted signal and operates to cause a corresponding negative transition of said output signal as well as to maintain said steady state after each of said corresponding positive and negative transitions; and
a level shifter circuit to generate a pair of signals to support operation of said hold and turn-off circuit.
